(19) United States
(12) Patent Application Publication
(10) Pub. No.: US 2014/0160269 A1
(43) Pub. Date: Jun. 12, 2014

(54) INTERPOSER TESTING DEVICE AND METHOD THEREOF

(71) Applicant: INDUSTRIAL TECHNOLOGY RESEARCH INSTITUTE, Hsinchu (TW)

(72) Inventors: Ka-Yi Yeh, Hsinchu (TW); Jui-Hung Chien, Taipei (TW)

(73) Assignee: Industrial Technology Research Institute, Hsinchu (TW)

(21) Appl. No.: 13/852,083

(22) Filed: Mar. 28, 2013

(30) Foreign Application Priority Data
Dec. 7, 2012 (TW) 101146219

(51) Int. Cl. G01R 31/04

(52) U.S. Cl. CPC G01R 31/041
USPC 348/87

(57) ABSTRACT

The disclosure provides an interposer testing device for testing an interposer and a method thereof which includes a heat source, a thermal image capturing device and a comparing device. The heat source is adapted for heating an area to be tested on the interposer. The thermal image capturing device is adapted for capturing a thermal image of the interposer after the interposer is heated. The comparing device is adapted for comparing the thermal image with a standard thermal image to output a comparison result.

### CROSS-REFERENCE TO RELATED APPLICATIONS

This non-provisional application claims priority under 35 U.S.C. §119(a) on Patent Application No(s). 101146219 filed in Taiwan, R.O.C. on Dec. 7, 2012, the entire contents of which are hereby incorporated by reference.

### TECHNICAL FIELD

The disclosure relates to an interposer testing device and a method thereof.

### BACKGROUND

Ever since the invention of an integrated circuit, the development of semiconductor technology continues to make progress. This results in the reduction in the volume of electronic components and the enhancement in the stacking density of the integrated circuit. The enhancement in integrated density comes from the downsizing of microchips, making it possible for more components to be integrated into a chip.

The stacking density of the integrated circuit is improved two-dimensionally. Although the advancement in lithographic technology has lead to the substantial improvement in a two-dimensional (2D) integrated circuit, many physical limitations still exist in the enhancement of stacking density in two-dimensional structures. One of the limitations is that the electronic components have to be made compactly. When more electronic components are formed on a chip, more complicated designs are required.

In order to offer a solution for the above manufacturing limitations, a three-dimensional integrated circuit (3D-IC) has been developed. The three-dimensional integrated circuit is a technology for enhancing the density of integrated circuit. In addition that the requirement of micro-dimensions can be achieved by enhancing the packing density through vertical interconnection, the integration of different materials is also feasible by closely connecting thin chips with different functions or of different materials. Alternatively, a chip packing technology which employs an interposer as the medium has been introduced, and the packed products using the technology are referred to as 2.5D chips hereafter. For 2.5D chips, different chips are connected through leads and connection points (i.e., contacts) on the interposer, and then the 2.5D chip is connected to an external system. In case any one of the leads or connection points of the interposer is defective, the 2.5 chip becomes failure because the different chips are out of function.

Like a conventional printed circuit board, the interposer generally doesn't equip with any active unit. Because the dimensions of the connection points of an interposer are very small relative to external world and the number of connection points is very large, it is very difficult to use a direct-contact measurement for ensuring whether all the leads and connection points are normal.

### SUMMARY

An embodiment of the disclosure provides an interposer testing device for testing an interposer. The interposer testing device comprises a heat source, a thermal image capturing device and a comparing device. The heat source is adapted for heating an area to be tested on the interposer. The thermal image capturing device is adapted for capturing a thermal image of the interposer after the interposer is heated. The comparing device is adapted for comparing the thermal image with a standard thermal image to output a comparison result.

Another embodiment of the disclosure provides an interposer testing method for testing an interposer comprising the following steps. An area to be tested is heated on the interposer by a heat source. A thermal image of the interposer is captured after the interposer is heated. The thermal image is compared with a standard thermal image to output a comparison result.

### BRIEF DESCRIPTION OF THE DRAWINGS

The disclosure will become more fully understood from the detailed description given herein below for illustration only, thus does not limit the disclosure, wherein:

FIG. 1 is a view of an interposer testing device according to an embodiment of the disclosure;

FIG. 2 is a view of a thermal image of the interposer testing device according to an embodiment of the disclosure;

FIG. 3 is a view of a thermal image of the interposer testing device according to an embodiment of the disclosure;

FIG. 4 is a view of a thermal image of the interposer testing device according to an embodiment of the disclosure;

FIG. 5 is a schematic view of the interposer testing device according to an embodiment of the disclosure; and

FIG. 6 is a flow chart of an interposer testing method according to an embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

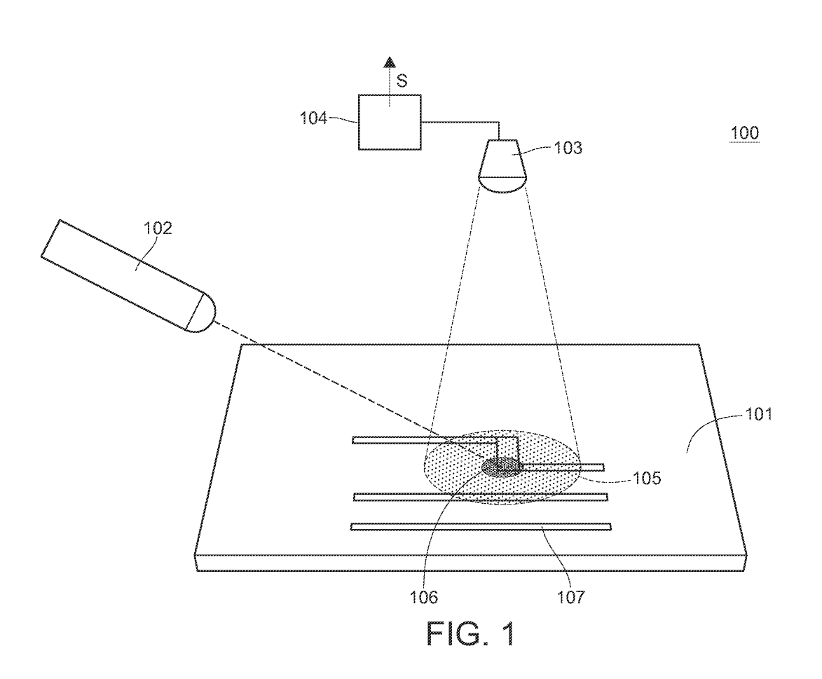

Please refer to FIG. 1, which is a view of an interposer testing device 100 according to an embodiment of the disclosure. The interposer testing device 100 is adapted for testing an interposer 101. The interposer testing device 100 comprises a heat source 102, a thermal image capturing device 103 and a comparing device 104.

As shown in FIG. 1. The heat source 102 is adapted for heating an area to be tested 105 on the interposer 101. The thermal image capturing device 103 is adapted for capturing a thermal image 106 of the heated interposer 101. The comparing device 104 is adapted for comparing the thermal image 106 with a standard thermal image A so as to output a comparison result S.

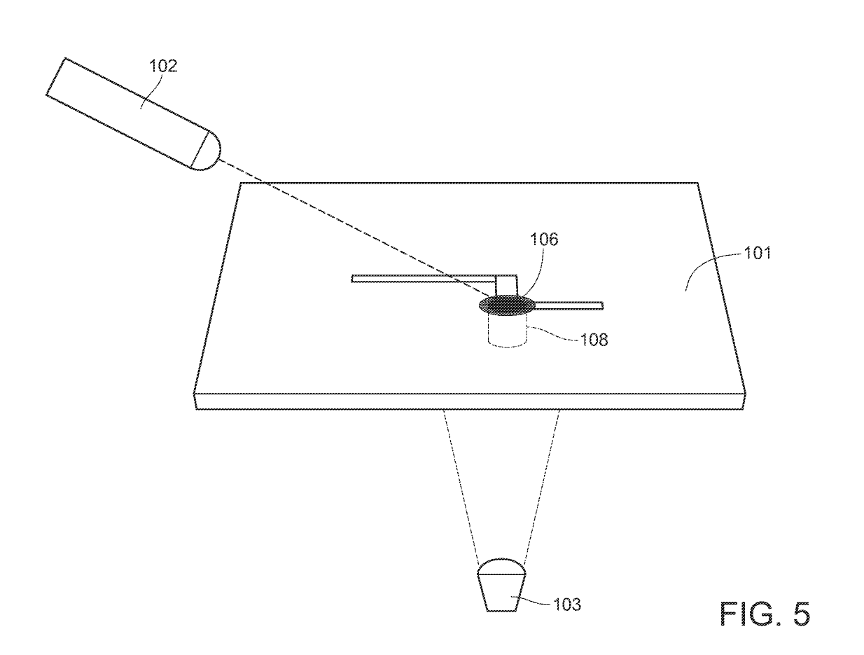

The heat source 102 is a laser, a microwave or a focus light source. The heat source 102 is adapted for heating the area to be tested 105. In other embodiments, the heat source 102 may also be a device for transmitting heat through radiation. In one embodiment, when the interposer 101 includes a plurality of metal wires 107 interconnected with each other, the area to be tested 105 is an area of the plurality of metal wires 107. Please refer to FIGS. 1 and 5 together, and FIG. 5 is a schematic view of the interposer testing device 100 according to another embodiment of the disclosure. In one embodiment, when the interposer 101 includes a plurality of vertical leads 108, the area to be tested 105 is an area of the plurality of vertical leads 108. However, only one vertical lead is shown in the figure for exemplary. In FIG. 1, the plurality of metal wires 107 are formed in the interposer 101 or on a surface of the interposer 101, and the plurality of metal wires 107 are usually referred to as leads disposed horizontally, i.e., parallel to a horizontal direction of the interposer 101. In FIG. 5, the plurality of vertical leads 108 are formed in the interposer 101 by disposing perpendicularly to the horizontal direction of the interposer 101. In an embodiment, the plurality of vertical leads 108 are, for example, through silicon vias (TSV). The heat source 102 heats up the interposer 101 for at least ten microseconds. The area to be tested 105 is smaller than an area of the interposer 101.

Please refer to FIG. 1, the interposer 101 is that the plurality of metal wires 107 are formed and distributed on a substrate and adapted for connecting different chips with each other. The interposer 101 may be referred to as a downsized circuit board. In the testing of common circuit boards, it has to determine whether all the points (i.e., contacts) needed to be connected are connected, and whether the points that are not needed to be connected are disconnected, which is referred to as the open-short test. Because the interposer 101 is usually manufactured by an integrated circuit processing, the area and thickness of the interposer 101 can be downsized to a degree that may compare to an integrated circuit. With such dimensions, it is a very difficult task to measure the electrical properties and to perform the open-short test for every one of the metal wires 107.

The interposer testing device 100 provided by the disclosure employs the ratio of the thermal conductivity and the electrical conductivity of the metal with positive correlation based on the Wiedemann-Franz Law, and the difference of the thermal conductivity of the metal and the base-plate is used for determining whether the metal of the interposer 101 can conduct electronic signals based on the thermal conduction results.

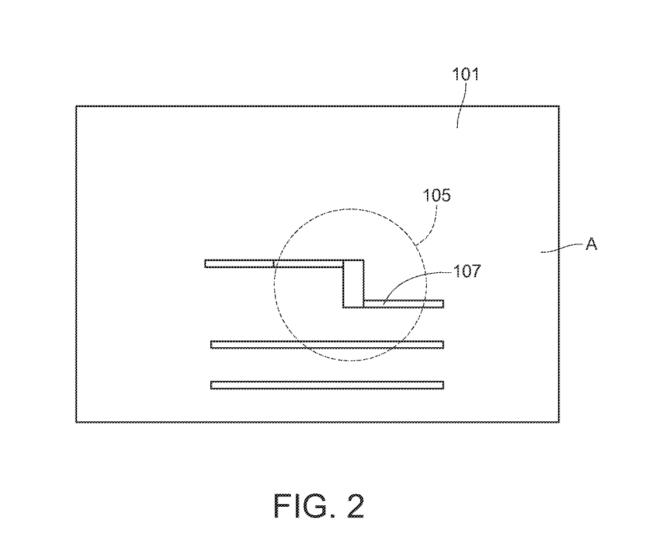

Please continue to refer to FIG. 1, when the interposer 101 is in a thermal equilibrium state, the interposer 101 and the plurality of metal wires 107 are at a same temperature. At this point, when the thermal image capturing device 103 is adapted for capturing a thermal image, the temperatures of both the interposer 101 and the plurality of metal wires 107 are the same. After the area to be tested 105 with the metal wires 107 is heated up, a large portion of energy will be transmitted to an area with a relatively lower temperature from an area with the smallest thermal resistance, which is the area of the plurality of metal wires 107. Therefore, the plurality of metal wires 107, connected to the area to be tested 105 will also be heated up afterwards. After a certain time period of heating by the heat source 102, the temperature of the plurality of metal wires 107 increases. At this point, when the thermal image capturing device 103 is adapted for capturing a thermal image of the interposer 101, the plurality of heated metal wires 107 in the area to be tested 105 may be seen, observed or measured, as shown in FIG. 2, which is a view of a thermal image of the interposer testing device according to an embodiment of the disclosure.

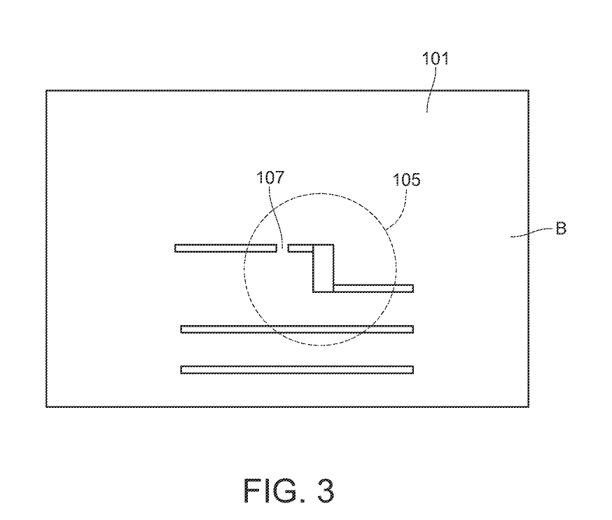

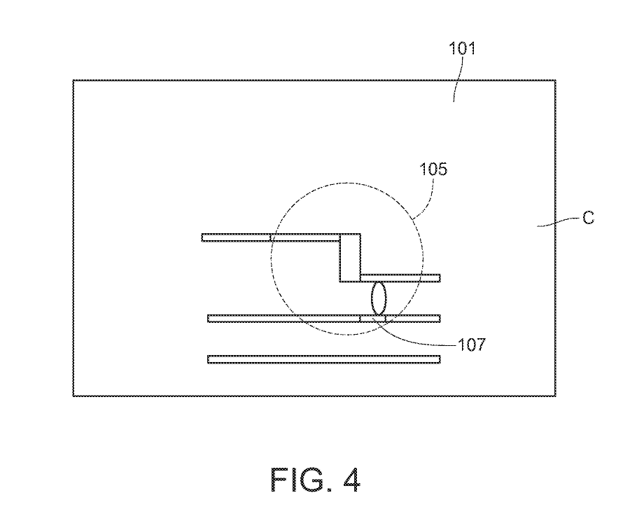

If failures, such as defects or open circuit, occur during the manufacturing process of the plurality of metal wires 107, the temperature will decrease sharply because the plurality of metal wires 107 are disconnected and become thinner. Then, a thermal image captured by the thermal image capturing device 103 is different from standard status, as shown by an open circuited thermal image B in FIG. 3, which is a view of a thermal image of the interposer testing device according to an embodiment of the disclosure. When signal lines that are not meant to be connected are short circuited because of particles or impurities of the plurality of metal wires 107, then the heat is transmitted to the metal wires 107 that are not meant to be heated up through the electrically conductive impurities, as shown by a short circuited thermal image C in FIG. 4, which is a view of a thermal image of the interposer testing device according to an embodiment of the disclosure.

The standard thermal image A is captured by using a layout diagram of the interposer 101 and by using some thermal conduction simulation tools adapted for capturing a thermal image diagram of a certain point or area of the interposer 101 after heating. Therefore, a qualified standard image of the interposer 101 is captured. Otherwise, a thermal image captured from actual testing can be used as the standard image. The standard image is a normal image of the metal wires in the interposer 101. According to the above embodiment, when the plurality of the metal wires 107 interconnected with each other are disposed in the interposer 101, then the standard image is a thermal image of the normally interconnected metal wires 107. Please refer to FIG. 5, when the plurality of the vertical leads 108 is disposed in the interposer 101, then the standard image is a thermal image of the normally disposed vertical leads 108. In the testing, the thermal image of the interposer 101 is regarded as unqualified when the thermal image is not within an error range of the standard image. After a certain area has been tested, another test area can be selected for repeating the processes of heating, image capturing and comparing, until all of the areas to be tested 105 in the interposer 101 are tested.

Please refer to FIG. 5. The interposer testing device 100 can be used for testing a plurality of through silicon vias (TSV) of the interposer 101. The critical process in the manufacturing of the through silicon vias lies in a process of filling up the deep holes with electrical conductive metal. In order to pursue a higher performance, the through silicon vias with a smaller diameter and a higher aspect ratio of diameter to depth are the targets to be achieved during the manufacturing process. When the aspect ratio of diameter to depth is high, it is required to test whether the quality of the electrical conductive materials in the through silicon vias complies with the requirements. As shown in the drawing, a front side of the interposer 101 with the plurality of through silicon via 108 is heated up by the heat source 102, and a thermal image of a back side of the interposer 101 with an exit of the plurality of through silicon via 108 is captured by the thermal image capturing device 103. Similar to the principles used in the first embodiment, thermal conductive properties are used to analogize the manufacturing quality of the electrical conductor in the through silicon via 108. In this embodiment, the standard thermal image A is a thermal image of the interposer 101 when the electrical conductive materials in the through silicon via 108 comply with a predetermined quality. Furthermore, the areas to be tested are areas of the through silicon vias.

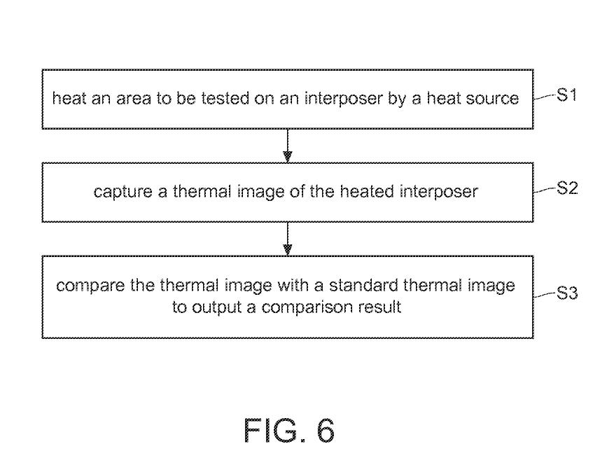

Please refer to FIGS. 1 and 6, FIG. 6 is a flow chart of the interposer testing method according to an embodiment of the disclosure. The interposer testing method provided by the disclosure is adapted for testing the interposer 101. The interposer testing method comprises the following steps. An area to be tested 105 on an interposer 101 is heated by a heat source 12 (step S1). A thermal image 106 of the heated interposer 101 is captured (step S2). The thermal image 106 is compared with the standard thermal image A to output the comparison result S (step S3).

The heat source 102 is a laser, a microwave or a focus light source. The heat source 102 is adapted for heating the area to be tested 105. The heat source 102 may also be a device for transmitting heat through radiation. When a plurality of metal wires 107 interconnected with each other is disposed in the interposer 101, the area to be tested 105 is an area of the plurality of metal wires 107. In FIG. 5, when a plurality of vertical leads 108 is disposed in the interposer 101, then the area to be tested 105 is an area of the plurality of vertical leads 108. The interposer testing method in FIG. 6 can also be applied in the interposer with the plurality of through silicon vias. The heat source 102 heats up the interposer 101 for at least ten microseconds. The area to be tested 105 is smaller than the area of the interposer 101.

The interposer 101 has a plurality of layers of leads and connection points, a plurality of chips are adhered on an upper surface and a lower surface of the interposer 101, and the plurality of connection points for packing are formed by penetrating the plurality of vertical leads 108 through the interposer 101. The wafers of the interposer 101 are made of, for example, silicon or glass, and one or the plurality of layers of the leads can be embedded on the chips. Similar to a conventional printed circuit board, only the plurality of leads and connection points are disposed on the interposer 101 before the adhering of the chips; except that, the area and thickness of the interposer 101 are substantially smaller than those of the printed circuit board. The main objective of testing is for ensuring whether or not each of the plurality of leads and connection points has defects from manufacturing, such as open or short circuit. Because the dimensions of the plurality of leads and connection points on the interposer 101 are small and the interposer 101 is not equipped with any active unit, the measurement methods of directly contacting or active circuit are not applicable. When the chips are adhered on the untested interposer 101, the chips will be wasted in case the interposer 101 is a defective product. The interposer testing device and the method thereof in the disclosure are a device and method for equivalently testing the electrical conductivity of the interposer 101 based on the thermal conductive characteristics of metal.

According to the interposer testing device and the method thereof in the disclosure, the heat source is employed to heat up the area to be tested on the interposer, the thermal image of the heated interposer is captured, and the thermal image is compared with the standard thermal image in order to deduce and determine whether the metal of the interposer is made normally for conducting electronic signals accurately based on the thermal conduction results. Thereby, the manufactured conditions of the interposer can be tested without directly contacting the interposer in order to reduce the problem of failed chips caused by the defects of the interposer and to enhance the success rate of chip production.

What is claimed is:

1. An interposer testing device for testing an interposer, the interposer testing device comprising:
a heat source for heating an area to be tested on the interposer;
a thermal image capturing device for capturing a thermal image of the interposer after the interposer is heated; and
a comparing device for comparing the thermal image with a standard thermal image to output a comparison result.

2. The interposer testing device according to claim 1, wherein the interposer includes a plurality of metal wires interconnected with each other.

3. The interposer testing device according to claim 2, wherein the area to be tested is an area of the plurality of metal wires.

4. The interposer testing device according to claim 2, wherein the standard thermal image is a thermal image of the metal wires when the plurality of metal wires are normally interconnected with each other.

5. The interposer testing device according to claim 1, wherein the interposer includes a plurality of vertical leads.

6. The interposer testing device according to claim 5, wherein the area to be tested is an area of the plurality of vertical leads.

7. The interposer testing device according to claim 5, wherein the standard thermal image is a thermal image of the plurality of vertical leads when the plurality of vertical leads are normally disposed.

8. The interposer testing device according to claim 1, wherein the interposer includes a plurality of through silicon vias.

9. The interposer testing device according to claim 8, wherein the area to be tested is an area of the plurality of through silicon vias.

10. The interposer testing device according to claim 8, wherein the standard thermal image is a thermal image of the interposer when an electrical conductive material in the through silicon vias comply with a predetermined quality.

11. The interposer testing device according to claim 1, wherein the heat source is a laser, a microwave or a focus light source.

12. The interposer testing device according to claim 1, wherein the heat source heats up the interposer for at least ten microseconds.

13. The interposer testing device according to claim 1, wherein the area to be tested is smaller than an area of the interposer.

14. An interposer testing method for testing an interposer, comprising steps of:
heating an area to be tested on the interposer by a heat source;
capturing a thermal image of the interposer after the interposer is heated; and
comparing the thermal image with a standard thermal image to output a comparison result.

15. The interposer testing method according to claim 14, wherein the interposer includes a plurality of metal wires interconnected with each other.

16. The interposer testing method according to claim 15, wherein the area to be tested is an area of the plurality of metal wires.

17. The interposer testing method according to claim 15, wherein the standard thermal image is a thermal image of the plurality of metal wires interconnected with each other.

18. The interposer testing method according to claim 14, wherein the interposer includes a plurality of vertical leads.

19. The interposer testing method according to claim 18, wherein the area to be tested is an area of the plurality of vertical leads.

20. The interposer testing method according to claim 18, wherein the standard thermal image is a thermal image of the vertical leads when the vertical leads are normally disposed.

21. The interposer testing method according to claim 14, wherein the interposer includes a plurality of through silicon vias.

22. The interposer testing method according to claim 21, wherein the area to be tested is an area of the plurality of through silicon vias.

23. The interposer testing method according to claim 21, wherein the standard thermal image is a thermal image of the interposer when an electrical conductive material in the through silicon vias comply with a predetermined quality.

24. The interposer testing method according to claim 14, wherein the heat source is a laser, a microwave or a focus light source.

25. The interposer testing method according to claim 14, wherein the heat source heats up the interposer for at least ten microseconds.

26. The interposer testing method according to claim 14, wherein the area to be tested is smaller than an area of the interposer.
